(19) United States
(12) Patent Application Publication
(10) Pub. No.: US 2013/0278123 A1
(43) Pub. Date: Oct. 24, 2013

(54) DEVICE HOUSING AND METHOD FOR MAKING THE SAME

(71) Applicant: KAI-RONG LIAO, Shenzhen City (CN)

(72) Inventor: KAI-RONG LIAO, Shenzhen City (CN)

(21) Appl. No.: 13/664,620

(22) Filed: Oct. 31, 2012

(30) Foreign Application Priority Data
Apr. 20, 2012 (CN) 201210117530.5

(51) Int. Cl. H05K 5/02; H05K 13/00

(52) U.S. Cl. 312/265.5; 216/39

(57) ABSTRACT

A housing includes a substrate, a connecting member and a latching member. The connecting member is formed on the substrate. The connecting member is made of phenylene pulfide. The latching member is formed on the connecting member. The latching member is made of polycarbonate.

### BACKGROUND

1. Technical Field

The present disclosure relates to a device housing and a method for making the device housing.

2. Description of Related Art

Metallic shells are widely used in many technological fields. One example is a metallic shell used with a portable electronic device (e.g., a mobile phone) for shielding internal electronic components. Typically, metallic shells are formed with plastic material, e.g. polycarbonate, configured for being latched with other components.

However, the bonding force between the metallic shell and the polycarbonate material layer is weak, and the polycarbonate material layer might be easily stripped from the metallic shell during daily use.

Therefore, there is room for improvement within the art.

### BRIEF DESCRIPTION OF THE FIGURE

Many aspects of the disclosure can be better understood with reference to the following figure. The components in the figure are not necessarily drawn to scale, the emphasis instead being placed upon clearly illustrating the principles of the disclosure.

FIG. 1 is a schematic view of an exemplary embodiment of a device housing

FIG. 2 is a cross-sectional view of the device housing in FIG. 1 taken along line II-II.

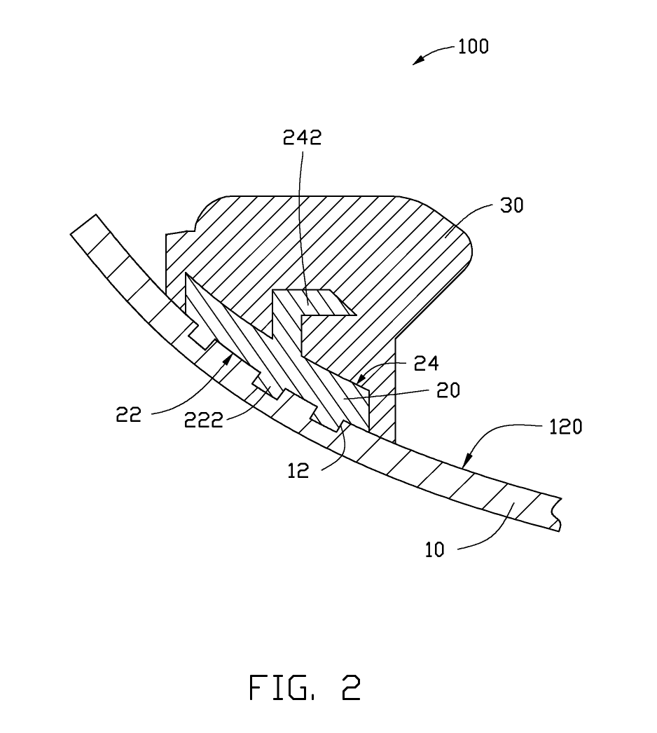

### DETAILED DESCRIPTION

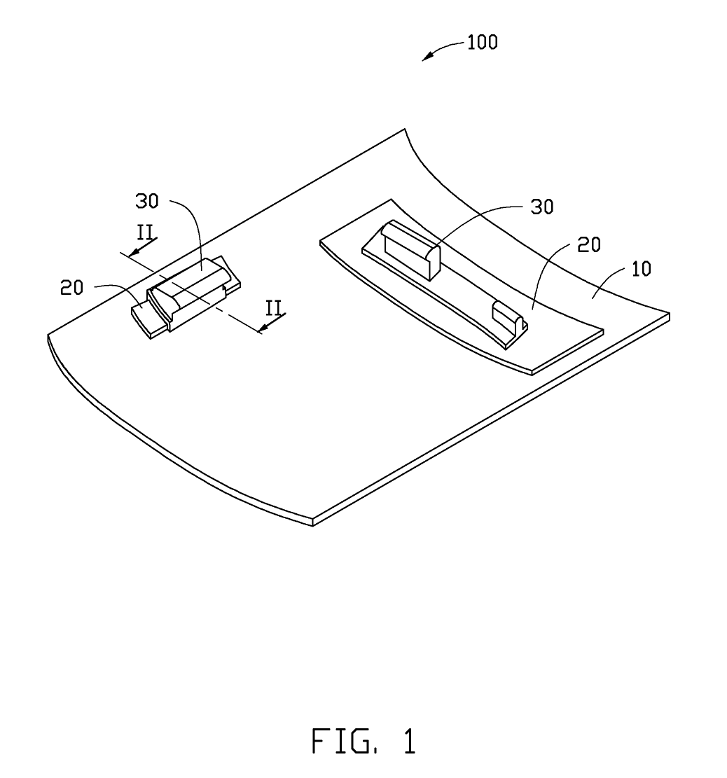

FIG. 1 shows a portion of a device housing 100 according to an exemplary embodiment. The housing 100 can be appropriately used with an electronic device, e.g. mobile phone, music player, computer and so on.

The housing 100 includes a substrate 10, a connecting member 20 formed on the substrate 10, and a latching member 30 formed on the connecting member 20.

The substrate 10 is made of metal, and includes an inner surface 120. The inner surface 120 defines a plurality of pores 12 configured for bonding the latching member 30. A diameter of each pore 12 is in a range of about 50 nm to about 80 nm. A depth of each pore 12 is in a range of about 50 nm to about 80 nm. Materials of the substrate 10 may be respectively selected from the group consisting of aluminum alloy, magnesium alloy, stainless steel, titanium alloy and so on. In the exemplary embodiment, material of the substrate 10 is made of aluminum alloy.

The connecting member 20 is embedded in the pores 12 of the substrate 10. The connecting member 20 includes a first surface 22 and a second surface 24. The first surface 22 has a plurality of projections 222 engaged in the pores 12. At least one hook 242 is formed on the second surface 24. Material of the connecting member 20 is made of phenylene pulfide (PPS). The connecting member 20 has a thickness of about 0.3 mm to about 0.5 mm.

The latching member 30 is formed on the connecting member 20. The shape of the latching member 30 depends on the predetermined requirement. In the exemplary embodiment, the latching member 30 is formed to clasps configured for engaging with other component. The latching member 30 is made of polycarbonate (PC). The connecting member 20 and the latching member 30 are fabricated by dual-injection molding.

A method for making the device housing 100 may include the following steps:

The substrate 10 is provided. The substrate 10 is chemically etched to define the pores 12. The substrate 10 is dipped in an etching solution. The inner surface 120 of the substrate 10 will chemically react with the compounds in the solution to form the pores 12. The pores 12 of the substrate 10 will enhance the adhesion of the connecting member 20 to the substrate 10 in a subsequent process. The etching time is about 5 min-about 10 min. After etching, the inner surface 120 of the substrate 10 undergoes a neutralization treatment and is rinsed with water.

Then, the substrate 10 is placed into a molding cavity of a mold apparatus, and a first molding material is injected into the molding cavity to integrally form the connecting member 20 on the substrate 10. In the exemplary embodiment, the first molding material is phenylene pulfide (PPS). The material of phenylene pulfide has a good flow property, and the melted phenylene pulfide can flow/fill into the pores 12 to form the projections 222 embedded in the pores 12 at one side of the connecting member 20. At the same time, the hook 242 is formed at an opposite side of the connecting member 20. The hook 242 of the substrate 10 will enhance the adhesion of the latching member 30 to the substrate 10 in a subsequent process.

After that, a second molding material is injected into the molding cavity, and integrally combines the substrate 10 and the connecting member 20 to form the housing 100. In the exemplary embodiment, the second molding material is polycarbonate. The polycarbonate molding material forms the predetermined shaped latching member 30. The latching member 30 encloses the hooks 242 on the connecting member 20.

Finally, the substrate 10 with the connecting member 20 and the latching member 30 is removed from the mold cavity.

The connecting member 20 made of phenylene pulfide is sandwiched between the substrate 10 and the latching member 30, and the latching member 30 made of polycarbonate can be stably connected to the substrate 10. Additionally, the pores 12 and the hook 242 can enhance the adhesion of among the connecting member 20, the latching member 30 and the substrate 10.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

1. A housing comprising:
a substrate;
a connecting member formed on the substrate, the connecting member made of phenylene pulfide; and
a latching member formed on the connecting member, the latching member made of polycarbonate.

2. The housing as claimed in claim 1, wherein the substrate comprises aluminum alloy.

3. The housing as claimed in claim 2, wherein the substrate defines a plurality of pores, the connecting member includes a first surface and a second surface, the first surface of the connecting member includes a plurality of projections embedded in the plurality of pores.

4. The housing as claimed in claim 3, wherein the second surface of the connecting member includes at least one hook, and the at least one hook is embedded in the latching member.

5. A method for making a device housing, comprising:
providing a substrate;
etching the substrate to define a plurality of pores;
placing the substrate into a mold cavity of an injection mold;
feeding phenylene pulfide to the mold cavity to fill the plurality of pores with phenylen pulfide to form a connecting member;
feeding polycarbonate on the connecting member to form a latching member on the substrate.

6. The method as claimed in claim 5, wherein the connecting member includes a first surface and a second surface, the first surface of the connecting member includes a plurality of projections embedded in the plurality of pores.

7. The method as claimed in claim 6, wherein the second surface of the connecting member includes at least one hook, the at least one hook is embedded in the latching member.
